(19) United States
(12) Patent Application Publication
(10) Pub. No.: US 2026/0344086 A1
(43) Pub. Date: Oct. 29, 2026

(54) IMAGE SENSOR HAVING DEEP TRENCH ISOLATION STRUCTURE

(71) Applicant: Samsung Electronics Co., Ltd., Suwon-si (KR)

(72) Inventors: Masato Fujita, Suwon-si (KR); Seung Ki Jung, Suwon-si (KR)

(73) Assignee: Samsung Electronics Co., Ltd., Suwon-si (KR)

(21) Appl. No.: 19/442,712

(22) Filed: Jan. 7, 2026

(30) Foreign Application Priority Data
Apr. 29, 2025 (KR) 10-2025-0056465

(51) Int. Cl. H10F 39/00

(52) U.S. Cl. CPC H10F 39/807; H10F 39/8023

(57) ABSTRACT

An image sensor comprises a plurality of unit pixels which constitute a shared pixel, and a DTI (deep trench isolation) structure which isolates the unit pixels from one another, wherein the DTI structure includes an internal DTI structure disposed inside the shared pixel, and an external DTI structure that surrounds the shared pixel, the internal DTI structure includes a pixel DTI structure that penetrates center of the shared pixel, is disposed between adjacent unit pixels, and a photoelectric DTI structure disposed between adjacent photodiodes in the unit pixels, each of the unit pixels includes a first photodiode, a second photodiode, a floating diffusion region that stores charges provided by the first photodiode and the second photodiode, a first active region on the first photodiode, and a second active region on the second photodiode, the first unit pixel includes a first source-follower gate on the first active region.

### CROSS-REFERENCE TO RELATED APPLICATIONS

This present application claims priority to and the benefit under 35 U.S.C. § 119(a)-(d) of Korean Patent Application No. 10-2025-0056465, filed on Apr. 29, 2025, in the Korean Intellectual Property Office, the entire disclosure of which is incorporated herein by reference.

### FIELD

The present disclosure relates to an image sensor and more particularly to an image sensor having a deep trench isolation structure.

### BACKGROUND

With continuous development of image sensor technology, CMOS image sensors are widely used in various fields such as a digital camera, a smartphone, a vehicle, a security, and a biomedicine. A conversion gain (CG) of a pixel cell is one of important indicators for evaluating a CMOS image sensor. The CG represents magnitude of a voltage change that electrons of a pixel cell may cause. The smaller a capacitance of a floating diffusion (FD) is, the larger the CG becomes. By improving the CG, it is advantageous to improve the sensitivity of the image sensor in a low illuminance environment and reduce the reading noise. Therefore, there is a need for a circuit design structure of an image sensor that may minimize the capacitance of the floating diffusion.

### SUMMARY

Aspects of the present disclosure provide an image sensor having improved performance and integration.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to aspects of the present disclosure, there is provided an image sensor comprising a plurality of unit pixels which constitute a shared pixel, and a DTI (deep trench isolation) structure which isolates the unit pixels from one another, wherein the DTI structure includes an internal DTI structure disposed inside the shared pixel, and an external DTI structure that surrounds the shared pixel, the internal DTI structure includes a pixel DTI structure that penetrates center of the shared pixel, extends in a first direction or in a second direction intersecting the first direction and is disposed between adjacent unit pixels, and a photoelectric DTI structure disposed between adjacent photodiodes in the unit pixels, each of the unit pixels includes a first photodiode, a second photodiode, a floating diffusion region that stores charges provided by the first photodiode and the second photodiode, a first active region on the first photodiode, and a second active region on the second photodiode, the first unit pixel includes a first source-follower gate on the first active region, and a source follower gate formed integrally by extending the first source-follower gate along the internal DTI structure is electrically connected to the floating diffusion region of each of the unit pixels.

According to embodiments of the present disclosure, there is provided an image sensor comprising, four unit pixels which constitute a shared pixel in a 2*2 structure, and a DTI (deep trench isolation) structure which isolates the unit pixels from one another, wherein the DTI structure includes an internal DTI structure disposed inside the shared pixel, and an external DTI structure that surrounds the shared pixel, the internal DTI structure includes a pixel DTI structure which passes through center of the shared pixel, extends in a first direction or a second direction intersecting the first direction and is disposed between adjacent unit pixels, and a photoelectric DTI structure which is disposed between adjacent photodiodes inside the unit pixel, wherein each of the unit pixels includes a first photodiode, a second photodiode, a floating diffusion region which stores charges provided by the first photodiode and the second photodiode, a first active region on the first photodiode, and a second active region on the second photodiode, the first unit pixel includes a first source-follower gate on the first active region, the second unit pixel includes a first reset gate on the first active region, the third unit pixel includes a second source-follower gate on the second active region, the first source-follower gate and the second source-follower gate are formed integrally, and a source-follower gate formed integrally by extending the first source-follower gate and the second source-follower gate along the internal DTI structure is in direct contact with a metal contact and electrically connected to the floating diffusion region of each of the unit pixels.

According to s embodiments of the present disclosure, there is provided an image sensor comprising, four unit pixels which constitute a shared pixel in a 2*2 structure, and a DTI (deep trench isolation) structure which isolates the unit pixels from one another, wherein the DTI structure includes an internal DTI structure disposed inside the shared pixel, and an external DTI structure that surrounds the shared pixel, the internal DTI structure includes a pixel DTI structure which passes through center of the shared pixel, extends in a first direction or a second direction intersecting the first direction and is disposed between adjacent unit pixels, and a photoelectric DTI structure which is disposed between adjacent photodiodes inside the unit pixel, wherein each of the unit pixels includes a first photodiode, a second photodiode, a floating diffusion region which stores charges provided by the first photodiode and the second photodiode, a first active region on the first photodiode, and a second active region on the second photodiode, the first unit pixel includes a first source-follower gate on the first active region, the second unit pixel includes a first reset gate on the first active region, the third unit pixel includes a second source-follower gate on the second active region, the first source-follower gate and the second source-follower gate are formed integrally, and a source-follower gate formed integrally by extending the first source-follower gate and the second source-follower gate along the internal DTI structure is in direct contact with a metal contact and electrically connected to the floating diffusion region of each of the unit pixels.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram simply showing an image sensor according to embodiments of the present disclosure.

FIG. 2 is a simplified diagram showing a pixel array included in the image sensor according to embodiments of the present disclosure.

FIG. 3 is a circuit diagram showing a simple pixel group of an image sensor according to embodiments of the present disclosure.

FIG. 4 is a plan view of a pixel group according to embodiments of the present disclosure.

FIG. 5 is a plan view showing only a partial configuration of the pixel group according to embodiments of the present disclosure.

FIG. 6 is a cross-sectional view showing a cross section taken along line I-I′ of FIG. 4.

FIGS. 7 to 11 are enlarged views showing only a region X of FIG. 6.

FIG. 12 is an enlarged view showing only a region Y of FIG. 6.

FIGS. 13 to 16 are plan views of a pixel group according to embodiments of the present disclosure.

FIG. 17 is a simplified diagram showing a pixel array included in an image sensor according to embodiments of the present disclosure.

FIG. 18 is a circuit diagram simply showing a pixel group of an image sensor according to embodiments of the present disclosure.

FIG. 19 is a plan view showing the pixel circuit shown in FIG. 18 on a substrate.

FIG. 20 is a plan view showing only a part of a pixel group according to embodiments of the present disclosure.

FIGS. 21 and 22 are plan views of a pixel group according to embodiments of the present disclosure.

### DETAILED DESCRIPTION

Hereinafter, embodiments of the present disclosure will be described in detail with reference to the accompanying drawings. The same reference numerals are used for the same components in the drawings, and their repeated description will not be provided.

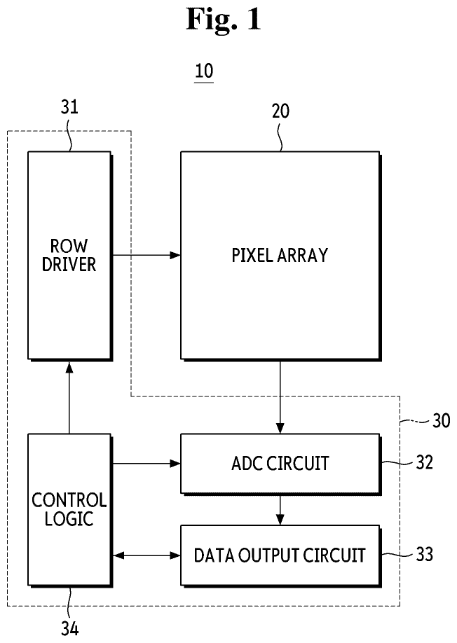

FIG. 1 is a block diagram simply showing an image sensor according to embodiments of the present disclosure.

Referring to FIG. 1, an image sensor 10 may include a pixel array 20, a peripheral circuit 30, and the like. The pixel array 20 may include a plurality of pixels disposed in the form of an array along a plurality of rows and a plurality of columns. Each of the plurality of pixels may include at least one photoelectric conversion element that generates charges in response to light, a pixel circuit that generates a voltage signal corresponding to the charge generated by the photoelectric conversion element, and the like. The photoelectric conversion element may include a photodiode formed of a semiconductor material, and/or an organic photodiode formed of an organic material.

For example, the pixel circuit may include a floating diffusion region, a transfer transistor, a reset transistor, a driving transistor, a selection transistor and the like. The configurations of the pixels may vary depending on the embodiments. For example, each of the pixels may include an organic photodiode including an organic material, or may be implemented as a digital pixel. When the pixels are implemented as digital pixels, each of the pixels may include an analog-digital converter for outputting a digital pixel signal.

The peripheral circuit 30 may include circuits for controlling the pixel array 20. For example, the peripheral circuit 30 may include a row driver 31, an analog-digital converter (ADC) circuit 32, a data output circuit 33, a control logic 34, and the like. The row driver 31 may drive the pixel array 20 on the basis of row lines. For example, the row driver 31 may generate a transfer control signal for controlling a transfer transistor of the pixel circuit, a reset control signal for controlling a reset transistor, a selection control signal for controlling a selection transistor, and the like, and input the signal to the pixel array 20 on a row line basis.

The ADC circuit 32 includes a plurality of correlated double samplers and a plurality of counters, and the correlated double samplers may be connected to the pixels through column lines. The correlated double samplers may read voltage signals from pixels connected to row lines selected by the row line selection signal of the row driver 31 through column lines. The analog-digital converter included in the ADC circuit 33 may convert the output of the correlated double samplers into digital pixel signals. For example, a latch or a buffer circuit capable of temporarily storing a digital pixel signal, and an amplifier circuit may be connected to an output terminal of the analog-digital converter. The control logic 34 may include a timing controller for controlling the operation timing of the row driver 31, the CDS circuit 32, and the ADC circuit 33 and the like.

Pixels disposed at the same position in a horizontal direction among the pixels may share the same column line. For example, the pixels disposed at the same position in a vertical direction may be simultaneously selected by the row driver 31, and output pixel signals through the column lines. In embodiments, the plurality of correlated double samplers included in the ADC circuit 32 may simultaneously receive voltage signals from pixels selected by the row driver 31 through the column lines. As an example, the plurality of correlated double samplers may sequentially receive a reset voltage and a pixel voltage from the pixel, and the pixel voltage may be a voltage in which the charges generated in each photodiode of the pixel are reflected in the reset voltage.

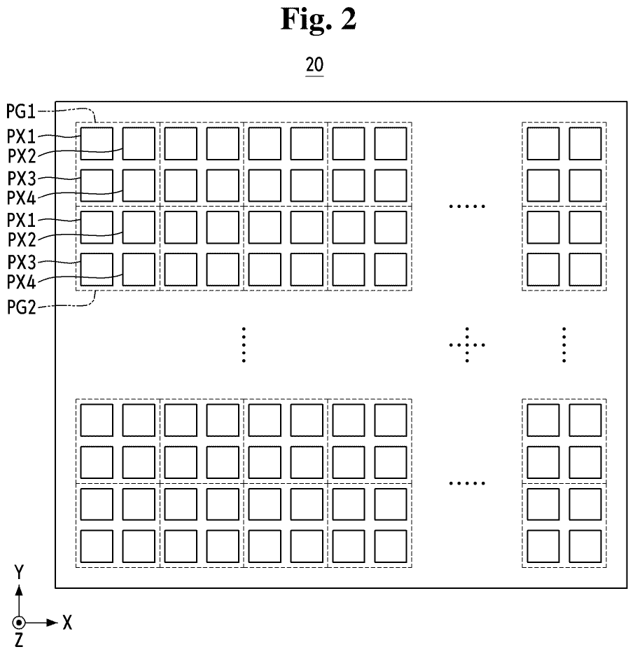

FIG. 2 is a simplified diagram showing a pixel array included in the image sensor according to embodiments of the present disclosure.

Referring to FIG. 2, the pixel array 20 according to embodiments of the present disclosure includes a plurality of pixel groups PG1 and PG2 arranged along a first direction X and a second direction Y, and a plurality of unit pixels may be disposed in the plurality of pixel groups PG1 and PG2. The plurality of unit pixels may be configured to output a voltage signal corresponding to the charges generated in response to light, and may be connected to a peripheral circuit by a plurality of row lines extending in the first direction and a plurality of column lines extending in the second direction.

As shown in FIG. 2, in the image sensor according to embodiments of the present disclosure, a first unit pixel PX1 and a second unit pixel PX2 adjacent to one another in the first direction X, a third unit pixel PX3 adjacent to the first unit pixel PX1 in the second direction Y intersecting the first direction X, and a fourth unit pixel PX4 adjacent to the second unit pixel PX2 in the second direction Y may be included in a single pixel group. Similarly, the pixel array 20 may have a plurality of pixel groups PG1 and PG2 arranged along the first and second directions. For example, the first pixel group PG1 may include a first unit pixel PX1 and a second unit pixel PX2 adjacent to one another in the first direction X, a third unit pixel PX3 adjacent to the first unit pixel PX1 in the second direction Y, and a fourth unit pixel PX adjacent to the second unit pixel PX2 in the second direction Y. The second pixel group PG2 is adjacent to the first pixel group PG1 in the second direction Y, and may include a first unit pixel PX1 and a second unit pixel PX2 adjacent to the third unit pixel PX3 and the fourth unit pixel PX4 of the first pixel group PG1 in the second direction Y, a third unit pixel PX3 adjacent to the first pixel group PG2 of the second pixel group PG2 in the second direction Y, and a fourth unit pixel PX4 adjacent to the second unit pixel PX2 of the second pixel group PG2 in the second direction Y.

Each of the plurality of pixel groups PG1 and PG2 may constitute a shared pixel.

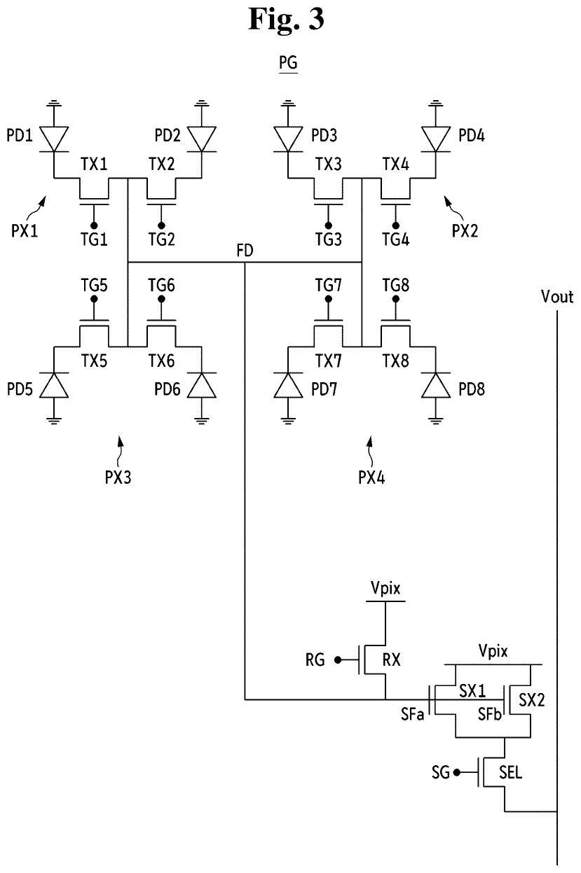

FIG. 3 is a circuit diagram showing a simple pixel group of an image sensor according to embodiments of the present disclosure.

Referring to FIG. 3, the pixel group PG may be the same as the first pixel group PG1 or the second pixel group PG2 of FIG. 2. The pixel group PG may include a pixel circuit that converts charges generated in each photodiode of the plurality of adjacent unit pixels into the voltage signal.

For example, the first unit pixel PX1 may include a first photodiode PD1 and a second photodiode PD2, and may include a first transfer transistor TX1 that connects the first photodiode PD1 to the floating diffusion region FD, and a second transfer transistor TX that connects the second photodiode PD2 to the floating diffusion region FD. The first transfer transistor TX1 may be controlled by a first transfer gate TG1. The second transfer transistor TX2 may be controlled by a second transfer gate TG2.

The second unit pixel PX2 may include a third photodiode PD3 and a fourth photodiode PD4, and may include a third transfer transistor TX3 that connects the third photodiode PD3 to the floating diffusion region FD, and a fourth transfer transistor TX4 that connects the fourth photodiode PD4 to the floating diffusion region FD. The third transfer transistor TX3 may be controlled by a third transfer gate TG3. The fourth transfer transistor TX4 may be controlled by a fourth transfer gate TG4.

The third unit pixel PX3 may include a fifth photodiode PD5 and a sixth photodiode PD6, and may include a fifth transfer transistor TX5 that connects the fifth photodiode PD5 and the floating diffusion region FD, and a sixth transfer transistor TX6 that connects the sixth photodiode PD6 and the floating diffusion region FD. The fifth transfer transistor TX5 may be controlled by a fifth transfer gate TG5. The sixth transfer transistor TX6 may be controlled by a sixth transfer gate TG6.

The fourth unit pixel PX4 may include a seventh photodiode PD7 and an eighth photodiode PD8, and may include a seventh transfer transistor TX7 that connects the seventh photodiode PD7 and the floating diffusion region FD, and an eighth transfer transistor TX7 that connects the eighth photodiode PD8 and the floating diffusion region FD. The seventh transfer transistor TX7 may be controlled by a seventh transfer gate TG7. The eighth transfer transistor TX8 may be controlled by an eighth transfer gate TG8.

The floating diffusion region FD may be connected to gates SFa and SFb of source-follower transistors SX1 and SX2 that operate as amplifiers.

Input terminals of the first source-follower transistor SX1 and the second source-follower transistor SX2 are connected to a power supply node that supplies a power supply voltage Vpix, and an output signal Vout may be output through the selection transistor SEL. When the selection transistor SEL is turned on by the selection transistor gate SG, the source-follower transistors SX1 and SX2 may amplify the voltage of the floating diffusion region FD to output the output signal Vout.

Meanwhile, a reset transistor RX may be connected between the floating diffusion region FD and the power supply node.

The reset transistor RX may include a reset gate RG. The reset transistor RX may be turned on in response to an active level of a reset signal applied to the reset gate RG to periodically reset the charges accumulated in the floating diffusion region FD.

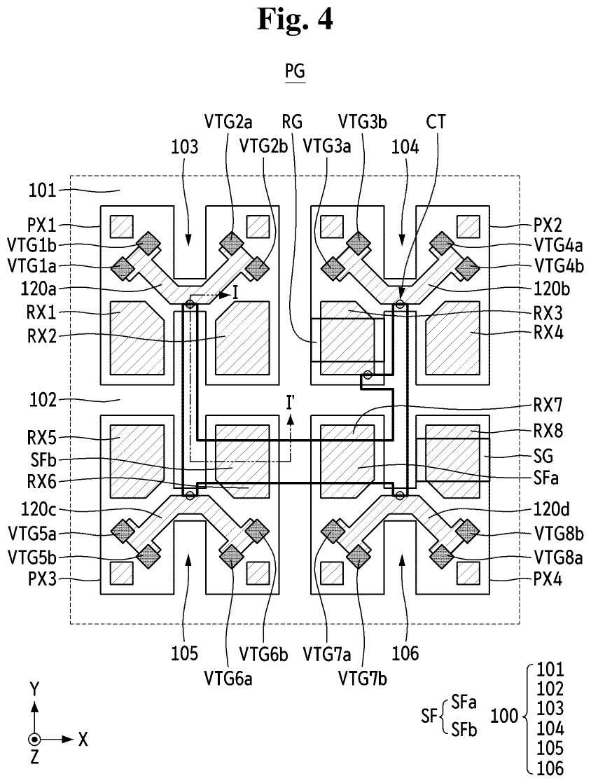

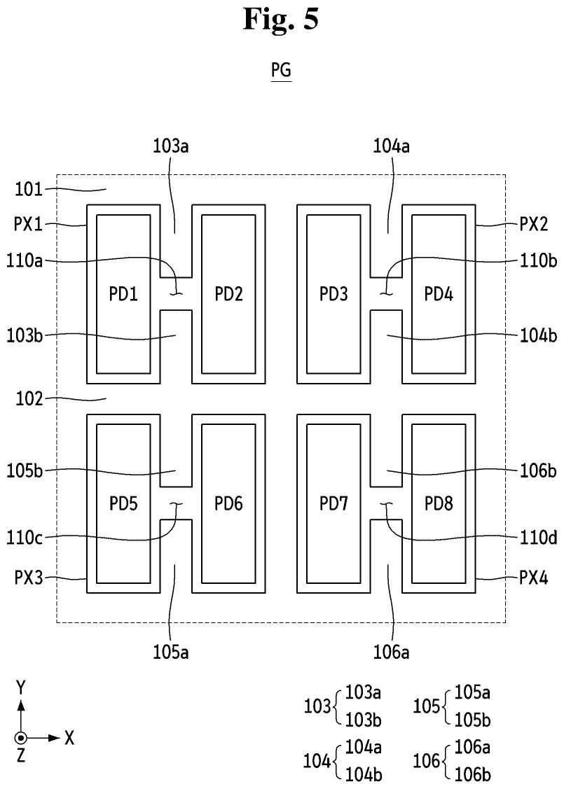

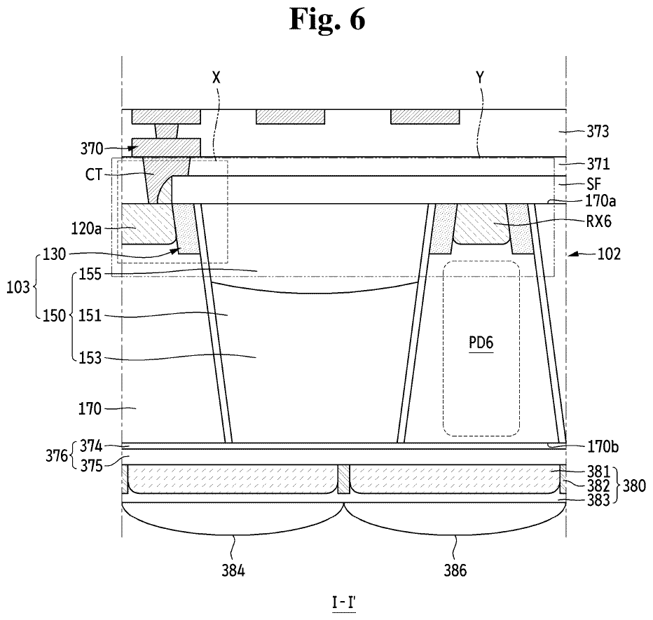

FIG. 4 is a plan view of a pixel group according to embodiments of the present disclosure. FIG. 5 is a plan view showing only a partial configuration of the pixel group according to embodiments of the present disclosure. FIG. 6 is a cross-sectional view showing a cross section taken along line I-I′ of FIG. 4.

Referring to FIGS. 4 to 6, the pixel circuit shown in FIG. 3 may be disposed on a substrate 170. The pixel group PG of FIGS. 4 to 6 may be the same as the first pixel group PG1 or the second pixel group PG2 of FIG. 2.

In some embodiments, the pixel group PG may include a first unit pixel PX1 and a second unit pixel PX2 adjacent to one another in the first direction X, and a third unit pixel PX3 and a fourth unit pixel PX4 adjacent to the first unit pixel PX1 and the second unit pixel PX2 in the second direction Y. The first unit pixel PX1 to the fourth unit pixel PX4 may form a shared pixel in the pixel group PG.

Each of the first unit pixel PX1 to the fourth unit pixel PX4 may include a plurality of photodiodes adjacent to one another in the first direction X. For example, the first unit pixel PX1 may include a first photodiode PD1 and a second photodiode PD2 that are adjacent to one another in the first direction X. The second unit pixel PX2 may include a third photodiode PD3 and a fourth photodiode PD4 that are adjacent to one another in the first direction X. The third unit pixel PX3 may include a fifth photodiode PD5 and a sixth photodiode PD6 that are adjacent to one another in the first direction X. The fourth unit pixel PX4 may include a seventh photodiode PD7 and an eighth photodiode PD8 that are adjacent to one another in the first direction X.

A plurality of pixel regions in which the first unit pixel PX1 to the fourth unit pixel PX4 are disposed may be defined by the DTI structure 100.

In some embodiments, the DTI structure 100 may include an external DTI structure 101 and internal DTI structures 102, 103, 104, 105, and 106.

The external DTI structure 101 may surround the shared pixel, and define a pixel group PG. The external DTI structure 101 may extend in the first direction X and the second direction Y, and may be formed to penetrate the substrate 170.

The internal DTI structure may be disposed inside the shared pixel. The internal DTI structures 102, 103, 104, 105, and 106 may include a pixel DTI structure 102 and photoelectric DTI structures 103, 104, 105, and 106.

The pixel DTI structure 102 may pass through the center of the shared pixel, and extend in the first direction X and the second direction Y. The pixel DTI structure 102 may be disposed between the unit pixels PX1, PX2, PX3, and PX4 and define the unit pixels PX1, PX2, PX3, and PX4.

The photoelectric DTI structures 103, 104, 105, and 106 may be disposed between adjacent photodiodes in each unit pixel. For example, the photoelectric DTI structures 103, 104, 105, and 106 may include a first photoelectric DTI structure 103, a second photoelectric DTI structure 104, a third photoelectric DTI structure 105, and a fourth photoelectric DTI structure 106. The first photoelectric DTI structure 103 may be disposed between the first photodiode PD1 and the second photodiode PD2 adjacent to one another in the first unit pixel PX1. The second photoelectric DTI structure 104 may be disposed between the third photodiode PD3 and the fourth photodiode PD4 adjacent to one another in the second unit pixel PX2. The third photoelectric DTI structure 105 may be disposed between the fifth photodiode PD5 and the sixth photodiode PD6 adjacent to one another in the third unit pixel PX3. The fourth photoelectric DTI structure 106 may be disposed between the seventh photodiode PD7 and the eighth photodiode PD8 adjacent to one another in the fourth unit pixel PX4.

Meanwhile, each of the first photoelectric DTI structure 103 to the fourth photoelectric DTI structure 106 may include first sub-DTI structures 103a, 104a, 105a, and 106a and second sub-DTI structures 103b, 104b, 105b, and 106b. A DTI center cut region DCC may be formed between the first sub-DTI structure 103a, 104a, 105a, and 106a and the second sub-DTI structure 103b, 104b, 105b, and 106b of the first photoelectric DTI structure 103 to the fourth photoelectric DTI structure 106.

The photoelectric DTI structures 103, 104, 105, and 106 extend in the second direction Y and may penetrate the substrate 170 in the same manner as the external DTI structure 101. The photoelectric DTI structures 103, 104, 105, and 106 may isolate the plurality of photodiodes in a pixel, using a frontside deep trench isolation (FDTI) pattern.

However, according to embodiments, the photoelectric DTI structures 103, 104, 105, and 106 may have a length in the third direction (Z-axis direction) that is shorter than the external DTI structure 101. In this case, charges may move between adjacent photodiodes in the unit pixel through a region in which the photoelectric DTI structures 103, 104, 105, and 106 are not formed.

A first transfer gate VTG1 and a second transfer gate VTG2 may be disposed in the first unit pixel PX1, and a third transfer gate VTG3 and a fourth transfer gate VTG4 may be disposed in the second unit pixel PX2. A fifth transfer gate VTG5 and a sixth transfer gate VTG6 may be disposed in the third unit pixel PX3. A seventh transfer gate VTG7 and an eighth transfer gate VTG8 may be disposed in the fourth unit pixel PX4.

Each of the first transfer gate VTG1 to the eighth transfer gate VTG8 may include a plurality of vertical transfer gates. For example, the first transfer gate VTG1 to the eighth transfer gate VTG8 may include a dual vertical transfer gate. The first transfer gate VTG1 may include a first sub-transfer gate VTG1a and a second sub-transfer gate VTG1b. The second transfer gate VTG2 may include a third sub-transfer gate VTG2a and a fourth sub-transfer gate VTG2b. The third transfer gate VTG3 may include a fifth sub-transfer gate VTG3a and a sixth sub-transfer gate VTG3b. The fourth transfer gate VTG4 may include a seventh sub-transfer gate VTG4a and an eighth sub-transfer gate VTG4b. The fifth transfer gate VTG5 may include a ninth sub-transfer gate VTG5a and a tenth sub-transfer gate VTG5b. The sixth transfer gate VTG6 may include an eleventh sub-transfer gate VTG6a and a twelfth sub-transfer gate VTG6b. The seventh transfer gate VTG7 may include a thirteenth sub-transfer gate VTG7a and a fourteenth sub-transfer gate VTG7b. The eighth transfer gate VTG8 may include a fifteenth sub-transfer gate VTG8a and a sixteenth sub-transfer gate VTG8b.

The first unit pixel PX1 may include a first floating diffusion region 120a on a first side 170a of the substrate 170. The second unit pixel PX2 may include a second floating diffusion region 120b on the first side 170a of the substrate 170. The third unit pixel PX3 may include a third floating diffusion region 120c on the first side 170a of the substrate 170. The fourth unit pixel PX4 may include a fourth floating diffusion region 120d on the first side 170a of the substrate 170.

Each of the first transfer gate VTG1 to the eighth transfer gate VTG8 may be adjacent to one of the first floating diffusion region 120a to the fourth floating diffusion region 120d. For example, in the first unit pixel PX1, the first transfer gate VTG1 and the second transfer gate VTG2 may be adjacent to the first floating diffusion region 120a. In the second unit pixel PX2, the third transfer gate VTG3 and the fourth transfer gate VTG4 may be adjacent to the second floating diffusion region 120b. In the third unit pixel PX3, the fourth transfer gate VTG4 and the fifth transfer gate VTG5 may be adjacent to the third floating diffusion region 120c. In the fourth unit pixel PX4, the seventh transfer gate VTG7 and the eighth transfer gate VTG8 may be adjacent to the fourth floating diffusion region 120d. Each of the first floating diffusion region 120a to the fourth floating diffusion region 120d may be a region doped with a predetermined impurity.

The first floating diffusion region 120a adjacent to the first transfer gate VTG1 extends along a first DTI center cut region 110a between the first photoelectric DTI structures 103, and may be adjacent to the second transfer gate VTG2. The second floating diffusion region 120b adjacent to the third transfer gate VTG3 extends along a second DTI center cut region 110b between the second photoelectric DTI structures 104, and may be adjacent to the fourth transfer gate VTG4. The third floating diffusion region 120c adjacent to the fifth transfer gate VTG5 extends along a third DTI center cut region 110c between the third photoelectric DTI structures 105, and may be adjacent to the sixth transfer gate VTG6. The fourth floating diffusion region 120d adjacent to the seventh transfer gate VTG7 extends along a fourth DTI center cut region 110d between the fourth photoelectric DTI structures 106, and may be adjacent to the eighth transfer gate VTG8.

Each of the unit pixels PX1, PX2, PX3, and PX4 included in the pixel group PG may include a plurality of active regions RX1, RX2, RX3, RX4, RX5, RX6, RX7, and RX8. For example, the first unit pixel PX1 may include a first active region RX1 and a second active region RX2 on the first side 170a of the substrate 170. The second unit pixel PX2 may include a third active region RX3 and a fourth active region RX4 on the first side 170a of the substrate 170. The third unit pixel PX3 may include a fifth active region RX5 and a sixth active region RX6 on the first side 170a of the substrate 170. The fourth unit pixel PX4 may include a seventh active region RX7 and an eighth active region RX8 on the first side 170a of the substrate 170.

In some embodiments, a reset gate RG may be disposed on the first side 170a of the substrate 170 adjacent to the third active region RX3, a first source-follower gate SFa may be disposed on the first side 170a of the substrate 170 adjacent to the seventh active region RX7, a second source-follower gate SFb may be disposed on the first side 170a of the substrate 170 adjacent to the sixth active region RX6, and a selection transistor gate SG may be disposed on the first side 170a of the substrate 170 adjacent to the eighth active region RX8.

In some embodiments, the source-follower gate SF may include a first source-follower gate SFa and a second source-follower gate SFb that are configured integrally. The source-follower gate SF may extend along the internal DTI structures 102, 103, 104, 105, and 106, and may be electrically connected to the first floating diffusion region 120a to the fourth floating diffusion region 120d. In addition, the source-follower gate SF may extend along the internal DTI structures 102, 103, 104, 105, and 106, and may be electrically connected to a third active region RX3 adjacent to the reset gate RG. In this way, instead of connecting the source-follower gate SF, the floating diffusion regions 120a, 120b, 120c, and 120d and the active region of the reset transistor RX through a metal wiring layer and a metal contact CT, by directly connecting the extending source-follower gate SF to the metal contact CT, the capacitance of the floating diffusion regions 120a, 120b, 120c, and 120d may decrease. Accordingly, the sensitivity of the image sensor is improved, and an image sensor with minimized noise may be provided. A specific form of the source-follower gate SF will be described below.

The internal DTI structures 102, 103, 104, 105, and 106 may include a first isolation pattern 150 and a second isolation pattern 130. For example, referring to FIG. 6, each of the pixel DTI structure 102, the first photoelectric DTI structure 103, and the third photoelectric DTI structure 105 may include a first isolation pattern 150 and a second isolation pattern 130.

The first isolation pattern 150 may extend from the first side 170a to the second side 170b of the substrate 170. The first isolation pattern 150 may be a deep trench isolation (DTI) film. The first isolation pattern 150 may penetrate the substrate 170. A vertical height of the first isolation pattern 150 may be substantially the same as a vertical thickness of the substrate 170. As an example, a width of the first isolation pattern 150 may gradually decrease from the first side 170a to the second side 170b of the substrate 170.

The first isolation pattern 150 may penetrate the second isolation pattern 130. At least a part of the second isolation pattern 130 may be in contact with the upper side wall of the first isolation pattern 150. The side wall and the lower side of the second isolation pattern 130 and the side wall of the first isolation pattern 150 may have a step-like structure. A depth of the second isolation pattern 130 may be smaller than a depth of the first isolation pattern 150.

The first isolation pattern 150 may include a first pattern 151, a second pattern 153, and a capping pattern 155. The first pattern 151 may be provided along a side wall of the deep trench DT. The first pattern 151 may include, as an example, a silicon-based insulating material (e.g., silicon nitride, silicon oxide, and/or silicon oxynitride) and/or a high dielectric constant material (e.g., hafnium oxide and/or aluminum oxide). As another example, the first pattern 151 may include a plurality of layers, and the layers may include different materials from one another. The first pattern 151 may have a lower refractive index than the substrate 170. This may prevent or reduce a crosstalk phenomenon between the unit pixel regions PX of the substrate 170.

The second pattern 153 may be provided inside the first pattern 151. For example, the side wall of the second pattern 153 may be surrounded by the first pattern 151. The first pattern 151 may be interposed between the second pattern 153 and the substrate 170. The second pattern 153 may be spaced apart from the substrate 170 by the first pattern 151. Thus, the second pattern 153 may be electrically isolated from the substrate 170 at the time of operation of the image sensor. The second pattern 153 may include a crystalline semiconductor material, for example, polycrystalline silicon. As an example, the second pattern 153 may further include a dopant, and the dopant may include an impurity of a first conductivity type or an impurity of a second conductivity type. For example, the second pattern 153 may include doped polycrystalline silicon. As another example, the second pattern 153 may include an undoped crystalline semiconductor material. For example, the second pattern 153 may include undoped polycrystalline silicon. The term “undoped” may mean that no intentional doping process is performed. The dopants may include n-type dopants and p-type dopants.

The capping pattern 155 may be provided on the upper side of the second pattern 153. The capping pattern 155 may be disposed adjacent to the first side 170a of the substrate 170. The upper side of the capping pattern 155 may be coplanar with the first side 170a of the substrate 170. The lower side of the capping pattern 155 may be substantially the same as the upper side of the second pattern 153. The capping pattern 155 may include a non-conductive material. As an example, the capping pattern 155 may include a silicon-based insulating material (e.g., silicon nitride, silicon oxide, and/or silicon oxynitride) and/or a high dielectric constant material (e.g., hafnium oxide and/or aluminum oxide). As a result, the first isolation pattern 150 may prevent photocharges generated by incident light incident on each unit pixel region PX from being incident on adjacent unit pixel regions PX1 to PX4 due to a random drift. That is, the first isolation pattern 150 may prevent a crosstalk phenomenon between the unit pixel regions PX1 to PX4.

The second isolation pattern 130 may be provided inside the substrate 170. The second isolation pattern 130 may be a shallow trench isolation (STT) film. The lower side of the second isolation pattern 130 may be provided inside the substrate 170.

A width of the second isolation pattern 130 may gradually decrease from the first side 170a to the second side 170b of the substrate 170.

The source-follower gate SF and the metal contact CT may be disposed in a first interlayer insulating film 371 disposed on the first side 170a of the substrate 170.

The plurality of wiring patterns 370 may be disposed inside a second interlayer insulating film 373 disposed on the first interlayer insulating film 371. The active regions of the source-follower gate SF, the floating diffusion regions 120a, 120b, 120c, and 120d, and the reset transistor RX may be electrically connected to the active regions of the first transfer gate VTG1 to the eighth transfer gate VTG8 disposed inside the pixel group PG, by the plurality of wiring patterns 370. The plurality of wiring patterns 370 may include contacts extending in the third direction Z, and metal wirings extending in the first direction and/or the second direction.

On the other hand, an optical region including a horizontal insulating layer 376, a color filter layer 380, microlenses 384 and 386, and the like may be disposed on the second side 170b of the substrate 170. The horizontal insulating layer 376 may include a first horizontal insulating layer 374 and a second horizontal insulating layer 375. For example, the first horizontal insulating layer 374 that is in contact with the substrate 170 may be formed of a material having a higher dielectric constant than the second horizontal insulating layer 375. The first horizontal insulating layer 374 may have a thickness smaller than the second horizontal insulating layer 375, and the first horizontal insulating layer 374 may cure some of the defects of the substrate 170.

The color filter layer 380 may include a color filter 381, a filter isolation film 382, a planarization layer 383, and the like. The filter isolation film 382 extends in the first direction X and the second direction Y, and thus, the color filter 381 may be arranged along a plurality of pixel regions. The planarization layer 383 may be disposed above the color filter 381, and the microlenses 384 and 386 may be disposed above the planarization layer 383. The microlenses 384 and 386 refract light incident from the outside to proceed to the color filter 380, and the color filter 380 may selectively allow light of a specific wavelength band to enter the photodiode.

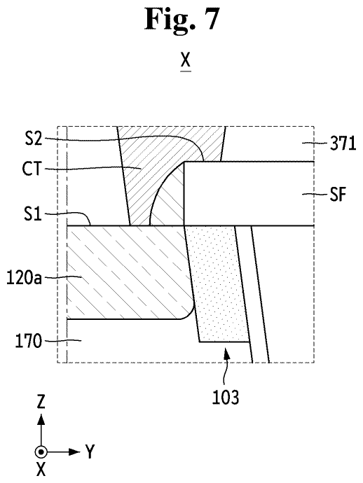

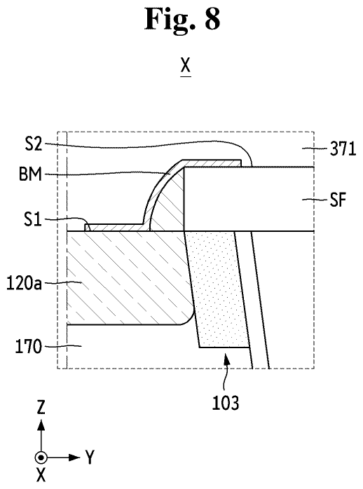

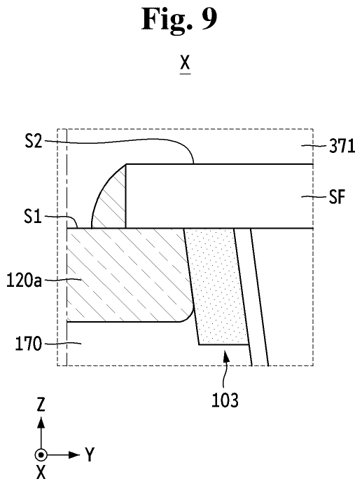

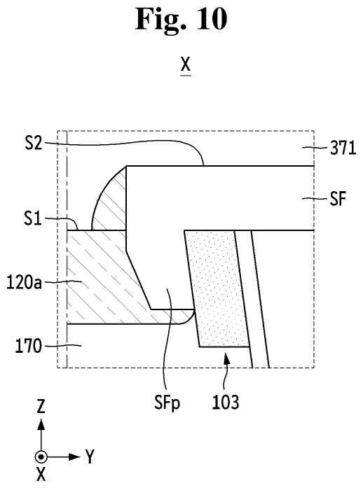

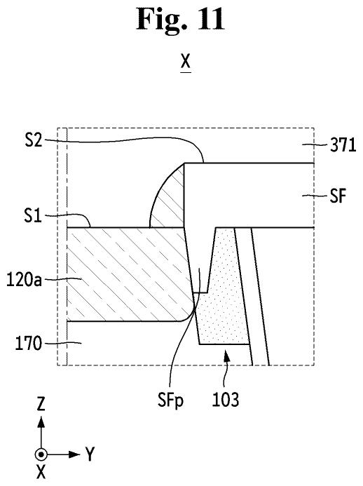

FIGS. 7 to 11 are enlarged views showing only a region X of FIG. 6.

Referring to FIGS. 4, 6, and 7, in some embodiments, the upper side S2 of the source-follower gate SF may be disposed at a higher level than the upper side S1 of the first floating diffusion region 120a. The source-follower gate SF and the first floating diffusion region 120a may not overlap in the third direction Z. Therefore, in the pixel group PG, the first floating diffusion region 120a and the source-follower gate SF may be electrically connected through a conductive film. For example, the conductive film may include a metal contact CT. Similarly, in the pixel group PG, the second floating diffusion region 120b to the fourth floating diffusion region 120d and the third active region RX3 adjacent to the reset gate RG may be electrically connected to the source-follower gate SF extending through the metal contact CT.

Referring to FIGS. 4, 6 and 8, in some embodiments, the upper side S2 of the source-follower gate SF may be disposed at a higher level than the upper side S1 of the first floating diffusion region 120a. The source-follower gate SF and the first floating diffusion region 120a may not overlap in the third direction Z. Therefore, the first floating diffusion region 120a and the source-follower gate SF may be electrically connected through a conductive film. For example, the conductive film may include a barrier metal BM. Similarly, in the pixel group PG, the second floating diffusion region 120b to the fourth floating diffusion region 120d and the third active region RX3 adjacent to the reset gate RG may be electrically connected to the source-follower gate SF extending through the barrier metal BM. By using the barrier metal BM, the capacitance of the floating diffusion regions 120a, 120b, 120c, and 120d may decrease. Accordingly, the sensitivity of the image sensor is improved, and an image sensor with minimized noise may be provided.

Referring to FIGS. 4, 6, and 9, in some embodiments, the upper side S2 of the source-follower gate SF may be disposed at a higher level than the upper side S1 of the first floating diffusion region 120a. The source-follower gate SF and the first floating diffusion region 120a may overlap in the third direction Z. Thus, the first floating diffusion region 120a and the source-follower gate SF may be directly connected. Similarly, in the pixel group PG, the second floating diffusion region 120b to the fourth floating diffusion region 120d and the third active region RX3 adjacent to the reset gate RG may be directly connected to the extending source-follower gate SF. By not using separate metal contact CT or barrier metal BM, the capacitance of the floating diffusion regions 120a, 120b, 120c, and 120d may decrease. Accordingly, the sensitivity of the image sensor is improved, and an image sensor with minimized noise may be provided.

Referring to FIGS. 4, 6, and 10, in some embodiments, the upper side S2 of the source-follower gate SF may be disposed at a higher level than the upper side S1 of the first floating diffusion region 120a. The source-follower gate SF may include a protrusion SFp that extends in the third direction Z and penetrates between the first floating diffusion region 120a and the first photoelectric DTI structure 103. For example, the protrusion SFp may be formed by removing a part of the first floating diffusion region 120a. Thus, the first floating diffusion region 120a and the source-follower gate SF may be directly connected. Similarly, inside the pixel group PG, the second floating diffusion region 120b to the fourth floating diffusion region 120d and the third active region RX3 adjacent to the reset gate RG may be directly connected to the extending source-follower gate SF. By not using separate metal contact CT or barrier metal BM, the capacitance of the floating diffusion regions 120a, 120b, 120c, and 120d may be decrease. Accordingly, the sensitivity of the image sensor is improved, and an image sensor with minimized noise may be provided.

Referring to FIGS. 4, 6, and 11, in some embodiments, the upper side S2 of the source-follower gate SF may be disposed at a higher level than the upper side S1 of the first floating diffusion region 120a. The source-follower gate SF may include a protrusion SFp that extends in the third direction Z and penetrates between the first floating diffusion region 120a and the first photoelectric DTI structure 103. For example, the protrusion SFp may be formed by removing a part of the first photoelectric DTI structure 103. Thus, the first floating diffusion region 120a and the source-follower gate SF may be directly connected. Similarly, in the pixel group PG, the second floating diffusion region 120b to the fourth floating diffusion region 120d and the third active region RX3 adjacent to the reset gate RG may be directly connected to the extending source-follower gate SF. By not using separate metal contact CT or barrier metal BM, the capacitance of the floating diffusion regions 120a, 120b, 120c, and 120d may decrease. Accordingly, the sensitivity of the image sensor is improved, and an image sensor with minimized noise may be provided.

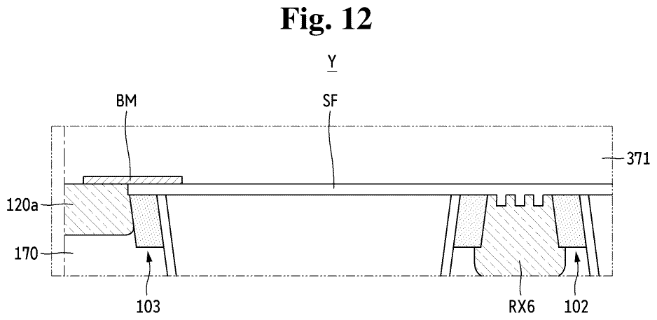

FIG. 12 is an enlarged view showing only a region Y of FIG. 6.

Referring to FIGS. 4, 6, and 12, in some embodiments, the upper side of the source-follower gate SF may be disposed at the same level as the upper side of the first floating diffusion region 120a. In the pixel group PG, the first floating diffusion region 120a and the source-follower gate SF may be electrically connected through a barrier metal BM. Similarly, in the pixel group PG, the second floating diffusion region 120b to the fourth floating diffusion region 120d and the third active region RX3 adjacent to the reset gate RG may be electrically connected to the extending source-follower gate SF through the barrier metal BM. Although the drawings only show that the first floating diffusion region 120a and the source-follower gate SF are electrically connected to one another through the barrier metal BM, embodiments of the present disclosure are not limited thereto. It goes without saying that the first floating diffusion region 120a and the source-follower gate SF may be electrically connected to one another through a metal contact.

In addition, the sixth active region RX6 and the source-follower gate SF may have a FinFET structure. Accordingly, the sensitivity of the image sensor is improved, and an integrated image sensor may be provided.

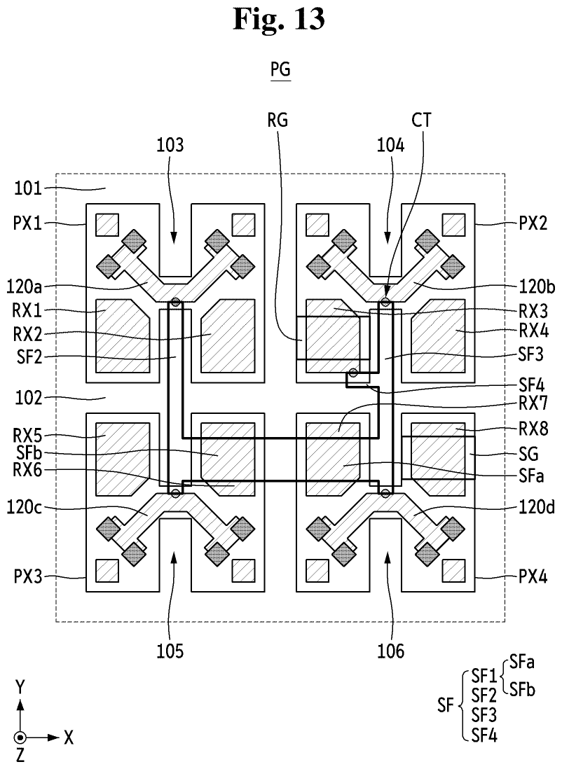

FIGS. 13 to 16 are plan views of a pixel group according to embodiments of the present disclosure. FIG. 13 is a plan view showing the pixel circuit shown in FIG. 3 on a substrate. FIG. 13 corresponds to a diagram corresponding to FIG. 4, and therefore the contents described in FIG. 4 will not be provided for the sake of convenience.

Referring to FIG. 13, in some embodiments, the pixel group PG may include an extending source-follower gate SF. The extending source-follower gate SF may include a first extending source-follower gate SF1, a second extending source-follower gate SF2, a third extending source-follower gate SF3, and a fourth extending source-follower gate SF4.

The first extending source-follower gate SF1 may include a first source-follower gate SFa and a second source-follower gate SFb. The first extending source-follower gate SF1 may be in a form in which the first source-follower gate SFa and the second source-follower gate SFb extend along the first direction X and are configured integrally.

The second extending source-follower gate SF2 may be disposed on the internal DTI structures 102, 103, 104, 105, and 106 between the first unit pixel PX1 and the third unit pixel PX3, and extend along the second direction Y to connect the first floating diffusion region 120a and the third floating diffusion region 120c.

The third extending source-follower gate SF3 may be disposed on the internal DTI structures 102, 103, 104, 105, and 106 between the second unit pixel PX2 and the fourth unit pixel PX4, and extend along the second direction Y to connect the second floating diffusion region 120b and the fourth floating diffusion region 120d.

The fourth extending source-follower gate SF4 may be disposed on the internal DTI structures 102, 103, 104, 105, and 106 between the second unit pixel PX2 and the fourth unit pixel PX4, and extend along the first direction X to connect the third extending source-follower gate SF3 and the third active region RX3 adjacent to the reset gate RG.

The first extending source-follower gate SF1 to the fourth extending source-follower gate SF4 may be configured integrally.

Instead of connecting the first source-follower gate SFa, the second source-follower gate SFb, the floating diffusion regions 120a, 120b, 120c, and 120d, and the active region of the reset transistor RX through a metal wiring layer and a metal contact CT, by directly connecting the extending source-follower gate SF to the metal contact CT, the capacitance of the metal regions 120a, 120b, 120c, and 120d may decrease. Accordingly, the sensitivity of the image sensor is improved, and an image sensor with minimized noise may be provided.

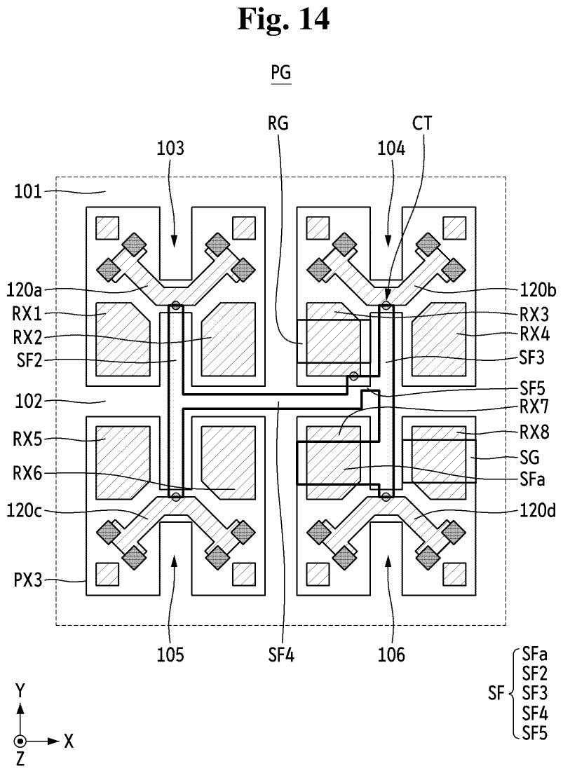

Referring to FIG. 14, in some embodiments, the pixel group PG may include an extending source-follower gate SF. The extending source-follower gate SF may include a first source-follower gate SFa, a second extending source-follower gate SF2, a third extending source-follower gate SF3, a fourth extending source-follower gate SF4, and a fifth extending source-follower gate SF5.

The second extending source-follower gate SF2 may be disposed on the internal DTI structures 102, 103, 104, 105, and 106 between the first unit pixel PX1 and the third unit pixel PX3, and extend along the second direction Y to connect the first floating diffusion region 120a and the third floating diffusion region 120c.

The third extending source-follower gate SF3 may be disposed on the internal DTI structures 102, 103, 104, 105, and 106 between the second unit pixel PX2 and the fourth unit pixel PX4, and extend along the second direction Y to connect the second floating diffusion region 120b and the fourth floating diffusion region 120d.

The fourth extending source-follower gate SF4 may be disposed on the internal DTI structures 102, 103, 104, 105, and 106 and extend along the first direction X to connect the second extending source-follower gate SF2 and the third extending source-follower gate SF3.

The fifth extending source-follower gate SF5 may be disposed on the internal DTI structures 102, 103, 104, 105, and 106 between the second unit pixel PX2 and the fourth unit pixel PX4, and extend along the first direction X and the second direction Y to connect the third extending source-follower gate SF3 and the fourth extending source-follower gate SF4.

The first source-follower gate SFa, the second extending source-follower gate SF2 to the fifth extending source-follower gate SF5 may be configured integrally.

Instead of connecting the first source-follower gate SFa, the floating diffusion regions 120a, 120b, 120c, and 120d, and the active region of the reset transistor RX through a metal wiring layer and metal contact CT, by directly connecting the extending source-follower gate SF to the metal contact CT, the capacitance of the floating diffusion regions 120a, 120b, 120c, and 120d may decrease. Accordingly, the sensitivity of the image sensor is improved, and an image sensor with minimized noise may be provided.

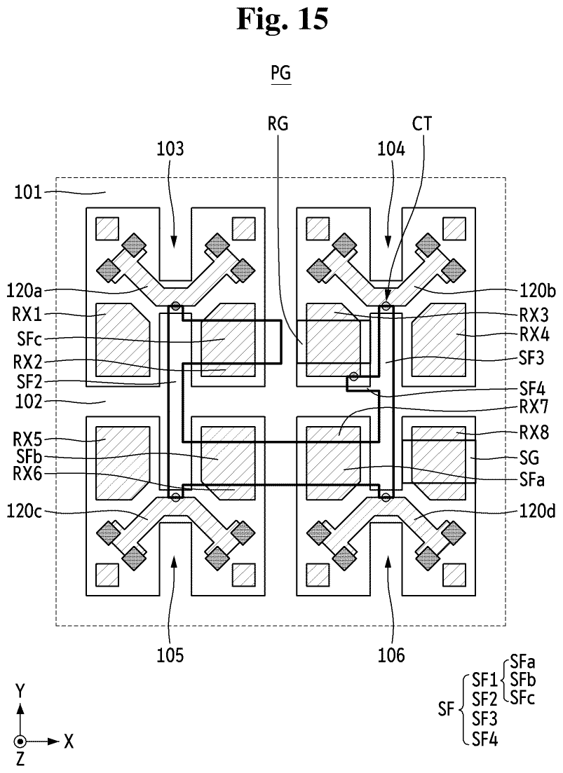

Referring to FIG. 15, in some embodiments, the pixel group PG may include an extending source-follower gate SF. The extending source-follower gate SF may include a first extending source-follower gate SF1, a second extending source-follower gate SF2, a third extending source-follower gate SF3, and a fourth extending source-follower gate SF4.

The first extending source-follower gate SF1 may include a first source-follower gate SFa, a second source-follower gate SFb, and a third source-follower gate SFc. The first source-follower gate SFa and the second source-follower gate SFb may be in a form in which they extend along the first direction X and are integrally configured.

The second extending source-follower gate SF2 may be disposed on the internal DTI structures 102, 103, 104, 105, and 106 between the first unit pixel PX1 and the third unit pixel PX3, and extend along the second direction Y to connect the first floating diffusion region 120a and the third floating diffusion region 120c.

The third extending source-follower gate SF3 may be disposed on the internal DTI structures 102, 103, 104, 105, and 106 between the second unit pixel PX2 and the fourth unit pixel PX4, and extend along the second direction Y to connect the second floating diffusion region 120b and the fourth floating diffusion region 120d.

The fourth extending source-follower gate SF4 may be disposed on the internal DTI structures 102, 103, 104, 105, and 106 between the second unit pixel PX2 and the fourth unit pixel PX4, and extend along the first direction X to connect the third extending source-follower gate SF3 and the third active region RX3 adjacent to the reset gate RG.

The first extending source-follower gate SF1 to the fourth extending source-follower gate SF4 may be configured integrally.

Instead of connecting the first source-follower gate SFa, the second source-follower gate SFb, the third source-follower gate SFc, the floating diffusion regions 120a, 120b, 120c, and 120d, and the active region of the reset transistor RX through a metal wiring layer and a metal contact layer CT, by directly connecting the extending source-follower gate SF to the metal contact CT, the capacitance of the floating diffusion regions 120a, 120b, 120c, and 120d may decrease. Accordingly, sensitivity of the image sensor is improved, and the image sensor with minimized noise may be provided.

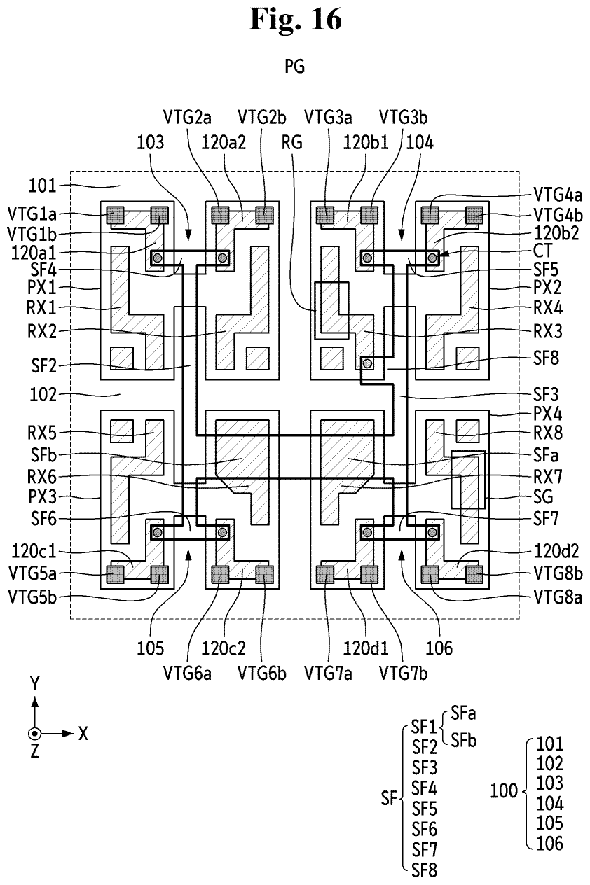

Referring to FIG. 16, in some embodiments, the pixel group PG may include an extending source-follower gate SF. The extending source-follower gate SF may include a first extending source-follower gate SF1, a second extending source-follower gate SF2, a third extending source-follower gate SF3, a fourth extending source-follower gate SF4, a fifth extending source-follower gate SF5, a sixth extending source-follower gate SF6, a seventh extending source-follower gate SF7, and an eighth extending source-follower gate SF8.

The first extending source-follower gate SF1 may include a first source-follower gate SFa and a second source-follower gate SFb. The first source-follower gate SFa and the second source-follower gate SFb may be in a form in which they extend along the first direction X and are configured integrally.

The second extending source-follower gate SF2 may be disposed on the internal DTI structures 102, 103, 104, 105, and 106 between the first unit pixel PX1 and the third unit pixel PX3, and extend along the second direction Y to connect the first extending source-follower gate SF1, the fourth extending source-follower gate SF4, and the sixth extending source-follower gate SF6.

The fourth extending source-follower gate SF4 may extend along the first direction X to connect the first floating diffusion region 120a1 and the second floating diffusion region 120a2.

The sixth extending source-follower gate SF6 may extend along the first direction X to connect the fifth floating diffusion region 120c1 and the sixth floating diffusion region 120c2.

The third extending source-follower gate SF3 may be disposed on the internal DTI structures 102, 103, 104, 105, and 106 between the second unit pixel PX2 and the fourth unit pixel PX4, and extend along the second direction Y to connect the first extending source-follower gate SF1, the fifth extending source-follower gate SF5, and the seventh extending source-follower gate SF7.

The fifth extending source-follower gate SF5 may extend along the first direction X to connect the third floating diffusion region 120b1 and the fourth floating diffusion region 120b2.

The seventh extending source-follower gate SF7 may extend along the first direction X to connect the seventh floating diffusion region 120d1 and the eighth floating diffusion region 120d2.

The eighth extending source-follower gate SF8 may be disposed on the internal DTI structures 102, 103, 104, 105, and 106 between the second unit pixel PX2 and the fourth unit pixel PX4, and extend along the first direction X to connect the third active regions RX3 adjacent to the reset gate RG.

The first extending source-follower gate SF1 to the eighth extending source-follower gate SF8 may be configured integrally.

Instead of connecting the first source-follower gate SFa, the second source-follower gate SFb, the floating diffusion regions 120a1, 120a2, 120b1, 120b2, 120c1, 120c2, 120d1, and 120d2 and the active region of the reset transistor RX through a metal wiring layer and a metal contact CT, by directly connecting the extending source-follower gate SF to the metal contact CT, the capacitance of the floating diffusion regions 120a1, 120a2, 120b1, 120b2, 120c1, 120c2, 120d1, and 120d2 may decrease. Accordingly, the sensitivity of the image sensor is improved, and an image sensor with minimized noise may be provided.

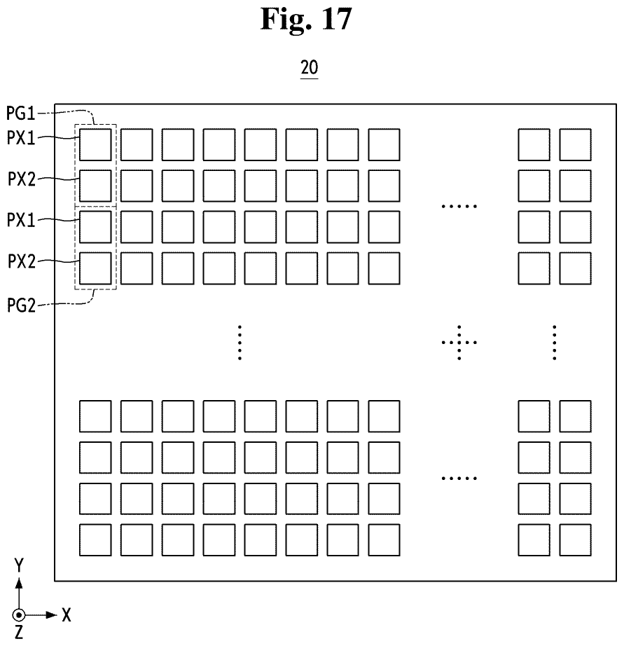

FIG. 17 is a simplified diagram showing a pixel array included in an image sensor according to embodiments of the present disclosure.

Referring to FIG. 17, a pixel array 20 according to embodiments of the present disclosure includes a plurality of pixel groups PG1 and PG2 arranged along the first direction X and the second direction Y, and a plurality of unit pixels may be disposed in the plurality of pixel groups PG1 and PG2. The plurality of unit pixels may be configured to output a voltage signal corresponding to charges generated in response to light, and may be connected to a peripheral circuit by a plurality of row lines extending in the first direction X and a plurality of column lines extending in the second direction.

In the image sensor according to embodiments of the present disclosure, the first unit pixel PX1 and the second unit pixel PX2 adjacent to one another in the second direction Y may be included in a single pixel group. Similarly, the pixel array 20 may include a plurality of pixel groups PG1 and PG2 arranged along the first direction X and the second direction Y. For example, the first pixel group PG1 may include a first unit pixel PX1 and a second unit pixel PX2 adjacent to one another in the second direction Y. The second pixel group PG2 is adjacent to the first pixel group PG1 in the second direction Y, and may include a first unit pixel PX1 and a second unit pixel PX2 that are adjacent to the first unit pixel PX1 and the second unit pixel PX2 of the first pixel group PG1 in the second direction Y.

The pixel group PG may constitute a shared pixel.

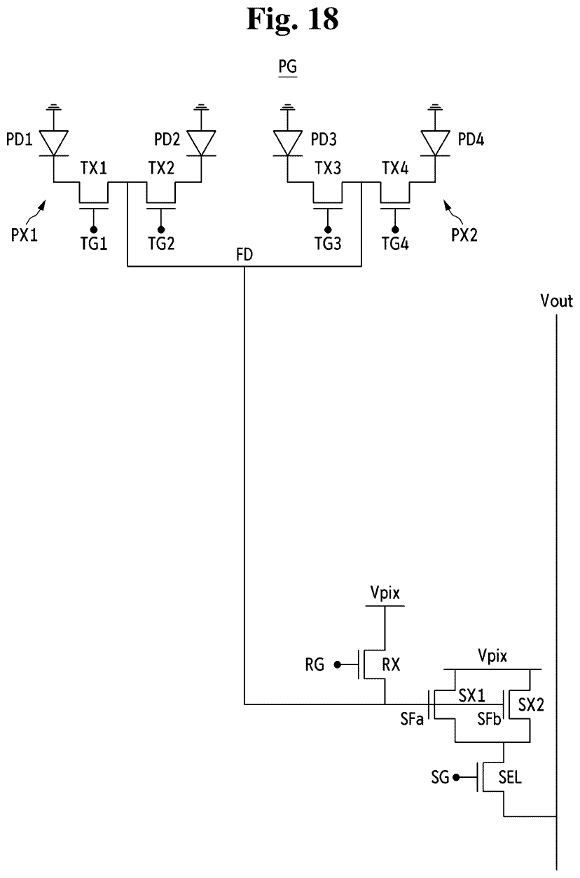

FIG. 18 is a circuit diagram simply showing a pixel group of an image sensor according to embodiments of the present disclosure.

Referring to FIG. 18, the pixel group PG may be the same as the first pixel group PG1 or the second pixel group PG2 of FIG. 16. Each of the plurality of pixel groups PG may include a pixel circuit that converts charges generated in each photodiode of the adjacent unit pixels into a voltage signal.

For example, the first unit pixel PX1 includes a first photodiode PD1 and a second photodiode PD2, and may include a first transfer transistor TX1 that connects the first photodiode PD1 to the floating diffusion region FD, and a second transfer transistor TX that connects the second photodiode PD2 to the floating diffusion region FD. The first transfer transistor TX1 may be controlled by the first transfer gate TG1. The second transfer transistor TX2 may be controlled by the second transfer gate TG2.

The second unit pixel PX2 includes a third photodiode PD3 and a fourth photodiode PD4, and may include a third transfer transistor TX3 that connects the third photodiode PD3 and the floating diffusion region FD, and a fourth transfer transistor TX4 that connects the fourth photodiode PD4 and the floating diffusion region FD. The third transfer transistor TX3 may be controlled by the third transfer gate TG3. The fourth transfer transistor TX4 may be controlled by the fourth transfer gate TG4.

The floating diffusion region FD may be connected to gates SFa and SFb of the source-follower transistors SX1 and SX2 that operate as amplifiers.

Input terminals of the first source-follower transistor SX1 and the second source-follower transistor SX2 are connected to a power supply node that supplies a power supply voltage Vpix, and an output signal Vout may be output through the selection transistor SEL. When the selection transistor SEL is turned on by the selection transistor gate SG, the source-follower transistors SX1 and SX2 may amplify the voltage of the floating diffusion region FD to output the output signal Vout.

Meanwhile, a reset transistor RX may be connected between the floating diffusion region FD and a power supply node.

The reset transistor RX may include a reset gate RG. The reset transistor RX may be turned on in response to the active level of the reset signal applied to the reset gate RG, and may periodically reset the charges accumulated in the floating diffusion region FD.

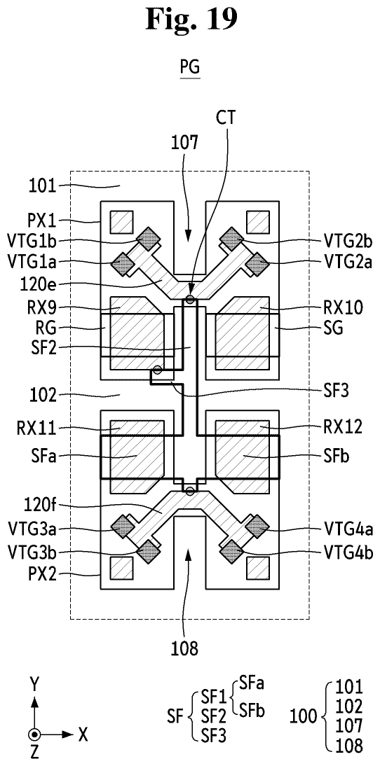

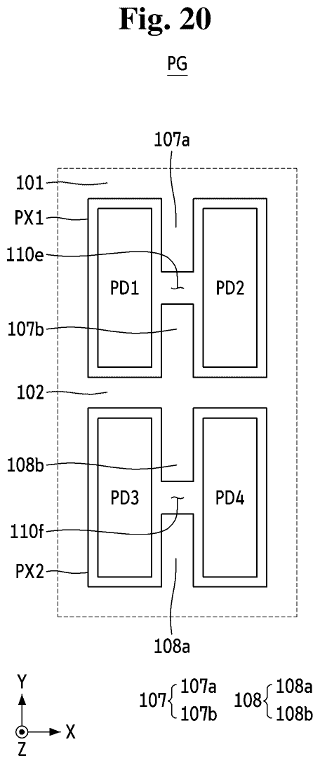

FIG. 19 is a plan view showing the pixel circuit shown in FIG. 18 on a substrate. FIG. 20 is a plan view showing only a part of a pixel group according to embodiments of the present disclosure.

Referring to FIGS. 19 and 20, the pixel circuit shown in FIG. 18 may be disposed on a substrate 170. The pixel group PG of FIGS. 19 and 20 may be the same as the first pixel group PG1 or the second pixel group PG2 of FIG. 16.

In some embodiments, the pixel group PG may include a first unit pixel PX1 and a second unit pixel PX2 that are adjacent to one another in the second direction Y. In the pixel group PG, the first unit pixel PX1 and the second unit pixel PX2 may constitute a shared pixel.

Each of the first unit pixel PX1 and the second unit pixel PX2 may include a plurality of photodiodes adjacent to one another in the first direction X. For example, the first unit pixel PX1 may include a first photodiode PD1 and a second photodiode PD2 that are adjacent to one another in the first direction X. The second unit pixel PX2 may include a third photodiode PD3 and a fourth photodiode PD4 that are adjacent to one another in the first direction X.

The plurality of pixel regions in which the first unit pixel PX1 and the second unit pixel PX2 are disposed may be defined by a DTI structure 100.

In some embodiments, the DTI structure 100 may include an external DTI structure 101 and internal DTI structures 102, 107, and 108.

The external DTI structure 101 may surround the shared pixel and define a pixel group PG. The external DTI structure 101 may extend in the first direction X and the second direction Y.

The internal DTI structure may be disposed inside the shared pixel. The internal DTI structures 102, 107, and 108 may include a pixel DTI structure 102 and photoelectric DTI structures 107 and 108.

The pixel DTI structure 102 may pass through the center of the shared pixel and extend in the first direction X. The pixel DTI structure 102 may be disposed between the unit pixels PX1 and PX2 and define the unit pixels PX1 and PX2.

The photoelectric DTI structures 107 and 108 may be disposed between adjacent photodiodes in each unit pixel. For example, the photoelectric DTI structures 107 and 108 may include a fifth photoelectric DTI structure 107 and a sixth photoelectric DTI structure 108. The fifth photoelectric DTI structure 107 may be disposed between adjacent first and second photodiodes PD1 and PD2 in the first unit pixel PX1. The sixth photoelectric DTI structure 108 may be disposed between the third photodiode PD3 and the fourth photodiode PD4 adjacent to one another in the second unit pixel PX2.

Meanwhile, each of the fifth photoelectric DTI structure 107 and the sixth photoelectric DTI structure 108 may include first sub-DTI structures 107a and 108a and second sub-DTI structures 107b and 108b. A DTI center cut region (DCC) may be formed between the first sub-DTI structures 107a and 108a and the second sub-DTI structures 107b and 108b of the fifth photoelectric DTI structure 107 and the sixth photoelectric DTI structure 108.

The photoelectric DTI structures 107 and 108 extend in the second direction Y, and may isolate a plurality of photodiodes in the pixel, using a frontside deep trench isolation (FDTI) pattern.

A first transfer gate VTG1 and a second transfer gate VTG2 may be disposed in the first unit pixel PX1, and a third transfer gate VTG3 and a fourth transfer gate VTG4 may be disposed in the second unit pixel PX2.

Each of the first transfer gate VTG1 to the fourth transfer gate VTG4 may include a plurality of vertical transfer gates. For example, the first transfer gate VTG1 to the fourth transfer gate VTG4 may include a dual vertical transfer gate. The first transfer gate VTG1 may include a first sub-transfer gate VTG1a and a second sub-transfer gate VTG1b. The second transfer gate VTG2 may include a third sub-transfer gate VTG2a and a fourth sub-transfer gate VTG2b. The third transfer gate VTG3 may include a fifth sub-transfer gate VTG3a and a sixth sub-transfer gate VTG3b. The fourth transfer gate VTG4 may include a seventh sub-transfer gate VTG4a and an eighth sub-transfer gate VTG4b.

The first unit pixel PX1 may include a fifth floating diffusion region 120e. The second unit pixel PX2 may include a sixth floating diffusion region 120f.

Each of the first transfer gate VTG1 to the fourth transfer gate VTG4 may be adjacent to one of the fifth floating diffusion region 120e and the sixth floating diffusion region 120f. For example, in the first unit pixel PX1, the first transfer gate VTG1 and the second transfer gate VTG2 may be adjacent to the fifth floating diffusion region 120e. In the second unit pixel PX2, the third transfer gate VTG3 and the fourth transfer gate VTG4 may be adjacent to the sixth floating diffusion region 120f. Each of the fifth floating diffusion region 120e and the sixth floating diffusion region 120f may be a region doped with a predetermined impurity.

The fifth floating diffusion region 120e adjacent to the first transfer gate VTG1 may extend along the fifth DTI center cut region 110e between the fifth photoelectric DTI structures 107, and may be adjacent to the second transfer gate VTG2. The sixth floating diffusion region 120f adjacent to the third transfer gate VTG3 may extend along the sixth DTI center cut region 110f between the sixth photoelectric DTI structures 108, and may be adjacent to the fourth transfer gate VTG4.

Each of the unit pixels PX1 and PX2 included in the pixel group PG may include a plurality of active regions RX9, RX10, RX11, and RX12. For example, the first unit pixel PX1 may include a ninth active region RX9 and a tenth active region RX10. The second unit pixel PX2 may include an eleventh active region RX11 and a twelfth active region RX12.

In some embodiments, the reset gate RG may be disposed adjacent to the ninth active region RX9, the selection transistor gate SG may be disposed adjacent to the ninth active region RX9, the first source-follower gate SFa may be disposed adjacent to the eleventh active region RX11, and the second source-follower gate SFb may be disposed adjacent to the twelfth active region RX12.

In some embodiments, the pixel group PG may include an extending source-follower gate SF. The extending source-follower gate SF may include a first extending source-follower gate SF1, a second extending source-follower gate SF2, and a third extending source-follower gate SF3.

The first extending source-follower gate SF1 may include a first source-follower gate SFa and a second source-follower gate SFb. The first extending source-follower gate SF1 may be in a form in which the first source-follower gate SFa and the second source-follower gate SFb extend along the first direction X and are configured integrally.

The second extending source-follower gate SF2 may be disposed on the internal DTI structures 102, 107, and 108 between the first unit pixel PX1 and the second unit pixel PX2, and extend along the second direction Y to connect a fifth floating diffusion region 120e and a sixth floating diffusion region 120f.

The third extending source-follower gate SF3 may be disposed on the internal DTI structures 102, 107, and 108 between the first unit pixel PX1 and the second unit pixel PX2, and extend along the first direction X to connect the second extending source-follower gate SF2 and a ninth active region RX9 adjacent to the reset gate RG.

The first extending source-follower gate SF1 to the third extending source-follower gate SF3 may be configured integrally.

Instead of connecting the first source-follower gate SFa, the second source-follower gate SFb, the floating diffusion regions 120e and 120f, and the active region of the reset transistor RX through a metal wiring layer and a metal contact CT, by directly connecting the extending source-follower gate SF to the metal contact CT, the capacitance of the floating diffusion regions 120e and 120f may decrease. Accordingly, the sensitivity of the image sensor is improved, and an image sensor with minimized noise may be provided.

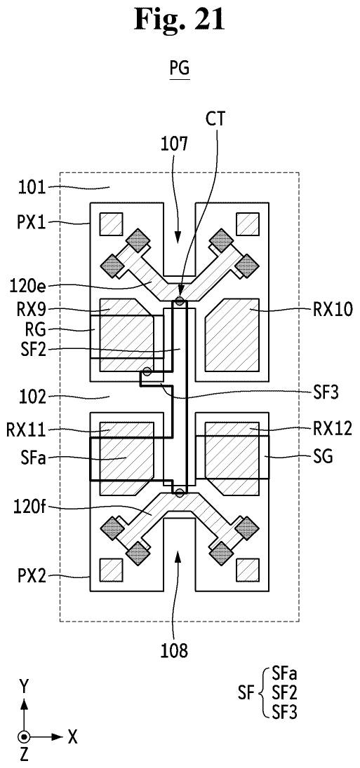

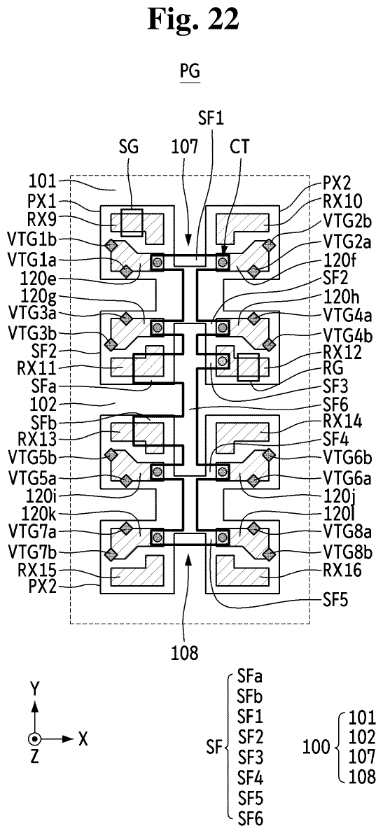

FIGS. 21 and 22 are plan views of a pixel group according to embodiments of the present disclosure.

Referring to FIG. 21, the pixel group PG may include an extending source-follower gate SF. The extending source-follower gate SF may include a first source-follower gate SFa, a second extending source-follower gate SF2, and a third extending source-follower gate SF3.

The second extending source-follower gate SF2 may be disposed on the internal DTI structures 102, 107, and 108 between the first unit pixel PX1 and the second unit pixel PX2, and extend along the second direction Y to connect the fifth floating diffusion region 120e and the sixth floating diffusion region 120f.

The third extending source-follower gate SF3 may be disposed on the internal DTI structures 102, 107, and 108 between the first unit pixel PX1 and the second unit pixel PX2, and extend along the first direction X to connect the second extending source-follower gate SF2 and a ninth active region RX9 adjacent to the reset gate RG.

The first source-follower gate SFa, the second extending source-follower gate SF2, and the third extending source-follower gate SF3 may be configured integrally.

Instead of connecting the first source-follower gate SFa, the floating diffusion regions 120e and 120f, and the active region of the reset transistor RX through a metal wiring layer and a metal contact CT, by directly connecting the extending source-follower gate SF to the metal contact CT, the capacitance of the floating diffusion regions 120e and 120f may decrease. Accordingly, sensitivity of the image sensor is improved, and an image sensor with minimized noise may be provided.

Referring to FIG. 22, the pixel group PG may include an extending source follower gate SF. The extending source-follower gate SF may include a first source-follower gate SFa, a second source-follower gate SFb, a first extending source-follower gate SF1, a second extending source-follower gate SF2, a third extending source-follower gate SF3, a fourth extending source-follower gate SF4, a fifth extending source-follower gate SF5, and a sixth extending source-follower gate SF5.

The first extending source-follower gate SF1 may be disposed on the first unit pixel PX1, and extend along the first direction X to connect the fifth floating diffusion region 120e and the sixth floating diffusion region 120f.

The second extending source-follower gate SF2 may be disposed on the first unit pixel PX1, and extend along the second direction Y to connect the seventh floating diffusion region 120g and the eighth floating diffusion region 120h.

The third extending source-follower gate SF3 may be disposed on the first unit pixel PX1, and extend along the first direction X to connect the sixth extending source-follower gate SF6 and the twelfth active region RX12 adjacent to the reset gate RG.

The fourth extending source-follower gate SF4 may be disposed on the second unit pixel PX2, and extend along the first direction X to connect the ninth floating diffusion region 120i to the tenth floating diffusion region 120j.

The fifth extending source-follower gate SF5 may be disposed on the second unit pixel PX2, and extend along the first direction X to connect the eleventh floating diffusion region 120k to the twelfth floating diffusion region 120l.

The sixth extending source-follower gate SF6 may be disposed on the internal DTI structures 102, 107, and 108 between the first unit pixel PX1 and the second unit pixel PX2, extend along the second direction Y, and be connected to the first source-follower gate SFa, the second source-follower gate SFb, the first extending source-follower gate SF1, the second extending source-follower gate SF2, the third extending source-follower gate SF3, the fourth extending source-follower gate SF4, and the fifth extending source-follower gate SF5.

The first source-follower gate SFa, the second source-follower gate SFb, and the first extending source-follower gate SF1 to the sixth extending source-follower gate SF6 may be configured integrally.

Instead of connecting the first source-follower gate SFa, the second source-follower gate SFb, the floating diffusion regions 120e, 120f, 120g, 120h, 120i, 120j, 120k, and 120l, and the active region of the reset transistor RX through the metal wiring layer and the metal contact CT, by directly connecting the extending source-follower gate SF to the metal contact CT, the capacitance of the floating diffusion regions 120e, 120f, 120g, 120h, 120i, 120j, 120k, and 120l may decrease. Accordingly, sensitivity of the image sensor is improved, and an image sensor with minimized noise may be provided.

According to aspects of the present disclosure, there is provided a method of manufacturing an image sensor comprising providing a plurality of unit pixels which constitute a shared pixel, and providing a DTI (deep trench isolation) structure which isolates the unit pixels from one another, wherein the DTI structure includes an internal DTI structure disposed inside the shared pixel, and an external DTI structure that surrounds the shared pixel, the internal DTI structure includes a pixel DTI structure that penetrates center of the shared pixel, extends in a first direction or in a second direction intersecting the first direction and is disposed between adjacent unit pixels, and a photoelectric DTI structure disposed between adjacent photodiodes in the unit pixels, each of the unit pixels includes a first photodiode, a second photodiode, a floating diffusion region that stores charges provided by the first photodiode and the second photodiode, a first active region on the first photodiode, and a second active region on the second photodiode, the first unit pixel includes a first source-follower gate on the first active region, and a source follower gate formed integrally by extending the first source-follower gate along the internal DTI structure is electrically connected to the floating diffusion region of each of the unit pixels.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. An image sensor comprising:
a plurality of unit pixels which constitute a shared pixel; and
a DTI (deep trench isolation) structure which isolates the unit pixels from one another, wherein:
the DTI structure includes an internal DTI structure disposed inside the shared pixel, and an external DTI structure that surrounds the shared pixel,
the internal DTI structure includes a pixel DTI structure that penetrates center of the shared pixel, extends in a first direction or in a second direction intersecting the first direction and is disposed between adjacent unit pixels, and a photoelectric DTI structure disposed between adjacent photodiodes in the unit pixels,
each of the unit pixels includes a first photodiode, a second photodiode, a floating diffusion region that stores charges provided by the first photodiode and the second photodiode, a first active region on the first photodiode, and a second active region on the second photodiode,
the first unit pixel includes a first source-follower gate on the first active region, and
a source follower gate formed integrally by extending the first source-follower gate along the internal DTI structure is electrically connected to the floating diffusion region of each of the unit pixels.

2. The image sensor of claim 1, wherein:
the second unit pixel includes a first reset gate on the first active region, and
the source-follower gate extends along the internal DTI structure and is electrically connected to the first active region of the second unit pixel.

3. The image sensor of claim 2, wherein:
the plurality of unit pixels include a first unit pixel, a second unit pixel, a third unit pixel, and a fourth unit pixel,
the shared pixel has a 2*2 structure,
the pixel DTI structure includes a first pixel DTI structure extending in the first direction, and a second pixel DTI structure extending in a second direction intersecting the first direction,
the photoelectric DTI structure includes:
a first photoelectric DTI structure disposed between adjacent photodiodes in the first unit pixel,
a second photoelectric DTI structure disposed between adjacent photodiodes in the second unit pixel,
a third photoelectric DTI structure disposed between adjacent photodiodes in the third unit pixel, and
a fourth photoelectric DTI structure disposed between adjacent photodiodes in the fourth unit pixel,
the extending source-follower gate includes:
the first source-follower gate,
a first sub-source-follower gate which extends along the first photoelectric DTI structure and the second photoelectric DTI structure,
a second sub-source-follower gate which extends along the third photoelectric DTI structure and the fourth photoelectric DTI structure,
a third sub-source-follower gate which extends along the first pixel DTI structure between the first sub-source-follower gate and the second sub-source-follower gate, and
a fourth sub-source-follower gate which connects the first active region of the second unit pixel to the first sub-source-follower gate and the third sub-source-follower gate, and
the first source-follower gate, and the first sub-source-follower gate to the fourth sub-source-follower gate are formed integrally.

4. The image sensor of claim 2, wherein:
the plurality of unit pixels include a first unit pixel and a second unit pixel.
the shared pixel has a 1*2 structure,
the photoelectric DTI structure includes:
a first photoelectric DTI structure which is disposed between adjacent photodiodes in the first unit pixel, and
a second photoelectric DTI structure which is disposed between adjacent photodiodes in the second unit pixel,
the extending source-follower gate includes:
the first source-follower gate,
a first sub-source-follower gate which extends along the first photoelectric DTI structure and the second photoelectric DTI structure, and
a second sub-source-follower gate which connects the first active region of the second unit pixel to the first sub-source-follower gate, and
the first source-follower gate, the first sub-source-follower gate, and the second sub-source-follower gate are formed integrally.

5. The image sensor of claim 1,
wherein:
the third unit pixel includes a second source-follower gate on the second active region, and
the source-follower gate and the second source-follower gate are formed integrally.

6. The image sensor of claim 1, wherein:
the first unit pixel includes a second source-follower gate on the second active region, and
the source-follower gate and the second source-follower gate are formed integrally.

7. The image sensor of claim 1,
wherein:
an upper side of the source-follower gate is disposed at a level higher than an upper side of the floating diffusion region,
the source-follower gate and the floating diffusion region do not overlap in a third direction intersecting the first direction and the second direction, and
the upper side of the source-follower gate and the upper side of the floating diffusion are electrically connected by a metal contact.

8. The image sensor of claim 7,
wherein the metal contact is in direct contact with the source-follower gate.

9. The image sensor of claim 1,
wherein:
the upper side of the source-follower gate is disposed at a level higher than a level of the upper side of the floating diffusion region, and
the source-follower gate and the floating diffusion region overlap in a third direction intersecting the first direction and the second direction.

10. The image sensor of claim 1,
wherein:
the upper side of the source-follower gate is disposed at a level higher than a level of the upper side of the floating diffusion region, and
the source-follower gate includes a protrusion penetrating between the floating diffusion region and the photoelectric DTI structure.

11. The image sensor of claim 1,
wherein:
the upper side of the source-follower gate is disposed at a same level as a level of the upper side of the floating diffusion region, and
the source-follower gate and the first active region have a FinFET structure.

12. An image sensor comprising:
a substrate including a first side and a second side;
a plurality of photodiodes which are disposed between the first side and the second side and form a shared pixel;
a DTI structure which is disposed between the first side and the second side, and isolates the plurality of photodiodes;
one or more floating diffusion regions which are formed on the first side and spaced apart from the photodiodes;
a first active region disposed on the first photodiode; and
a first source-follower gate disposed on the first active region,
wherein the DTI structure includes an internal DTI structure disposed inside the shared pixel, and an external DTI structure that surrounds the shared pixel,
the internal DTI structure includes a pixel DTI structure which passes through center of the shared pixel, extends in a first direction or in a second direction intersecting the first direction and is disposed between unit pixels forming the shared pixel, and a photoelectric DTI structure which is disposed between adjacent photodiodes inside the unit pixel,
the floating diffusion region accumulates charges provided from a plurality of photodiodes adjacent to one another across the photoelectric DTI structure, and
a source-follower gate formed integrally by extending the first source-follower gate along the internal DTI structure is electrically connected to the floating diffusion region of each of the unit pixels.

13. The image sensor of claim 12, further comprising:
a second active region disposed on a second photodiode,
wherein:
a first reset gate is included on the second active region, and
the source-follower gate extends along the DTI structure and is electrically connected to the second active region.

14. The image sensor of claim 13,
wherein:
the photodiodes include the first photodiode, a second photodiode, a third photodiode, a fourth photodiode, a fifth photodiode, a sixth photodiode, a seventh photodiode, and an eighth photodiode,
the pixel DTI structure includes a first pixel DTI structure extending in the first direction, and a second pixel DTI structure extending in the second direction intersecting the first direction,
the photoelectric DTI structure includes:
a first photoelectric DTI structure disposed between the first photodiode and the second photodiode,
a second photoelectric DTI structure disposed between the third photodiode and the fourth photodiode,
a third photoelectric DTI structure disposed between the fifth photodiode and the sixth photodiode, and
a fourth photoelectric DTI structure disposed between the seventh photodiode and the eighth photodiode,
the extending source-follower gate includes:
the first source-follower gate,
a first sub-source-follower gate which extends along the first photoelectric DTI structure and the second photoelectric DTI structure,
a second sub-source-follower gate which extends along the third photoelectric DTI structure and the fourth photoelectric DTI structure,
a third sub-source-follower gate which extends along the first pixel DTI structure between the first sub-source-follower gate and the second sub-source-follower gate, and
a fourth sub-source-follower gate which connects the second active region to the first sub-source-follower gate and the third sub-source-follower gate, and
the first source-follower gate, and the first sub-source-follower gate to the fourth sub-source-follower gate are formed integrally.

15. The image sensor of claim 13,
wherein:
the photodiode includes the first photodiode, the second photodiode, the third photodiode, and the fourth photodiode,
the photoelectric DTI structure includes:
a first photoelectric DTI structure disposed between the first photodiode and the second photodiode, and
a second photoelectric DTI structure disposed between the third photodiode and the fourth photodiode,
the extending source-follower gate includes:
the first source-follower gate,
a first sub-source-follower gate which extends along the first photoelectric DTI structure and the second photoelectric DTI structure, and
a second sub-source-follower gate which connects the second active region to the first sub-source-follower gate, and
the first source-follower gate, the first sub-source-follower gate, and the second sub-source-follower gate are formed integrally.

16. The image sensor of claim 13, further comprising:
a third active region disposed on the third photodiode; and
a second source-follower gate disposed on the third active region,
wherein the source-follower gate and the second source-follower gate are formed integrally.

17. The image sensor of claim 12,
wherein:
an upper side of the source-follower gate is disposed at a level higher than a level of an upper side of the floating diffusion region,
the source-follower gate and the floating diffusion region do not overlap in a third direction intersecting the first direction and the second direction, and
the upper side of the source-follower gate and the upper side of the floating diffusion are electrically connected by a metal contact.

18. The image sensor of claim 12,
wherein:
the upper side of the source-follower gate is disposed at a level higher than a level of the upper side of the floating diffusion region, and
the source-follower gate and the floating diffusion region overlap in the third direction intersecting the first direction and the second direction.

19. The image sensor of claim 12,
wherein:
the upper side of the source-follower gate is disposed at a level higher than a level of the upper side of the floating diffusion region, and
the source-follower gate includes a protrusion penetrating between the floating diffusion region and the photoelectric DTI structure.

20. An image sensor comprising:
four unit pixels which constitute a shared pixel in a 2*2 structure; and
a DTI (deep trench isolation) structure which isolates the unit pixels from one another,
wherein the DTI structure includes an internal DTI structure disposed inside the shared pixel, and an external DTI structure that surrounds the shared pixel,
the internal DTI structure includes a pixel DTI structure which passes through center of the shared pixel, extends in a first direction or a second direction intersecting the first direction and is disposed between adjacent unit pixels, and a photoelectric DTI structure which is disposed between adjacent photodiodes inside the unit pixel, wherein:
each of the unit pixels includes a first photodiode, a second photodiode, a floating diffusion region which stores charges provided by the first photodiode and the second photodiode, a first active region on the first photodiode, and a second active region on the second photodiode,
the first unit pixel includes a first source-follower gate on the first active region,
the second unit pixel includes a first reset gate on the first active region,
the third unit pixel includes a second source-follower gate on the second active region, the first source-follower gate and the second source-follower gate are formed integrally, and
a source-follower gate formed integrally by extending the first source-follower gate and the second source-follower gate along the internal DTI structure is in direct contact with a metal contact and electrically connected to the floating diffusion region of each of the unit pixels.
